(19) United States
(12) Patent Application Publication
(10) Pub. No.: US 2016/0013276 A1
(43) Pub. Date: Jan. 14, 2016

(54) NITRIDE SEMICONDUCTOR DEVICE

(71) Applicant: SHARP KABUSHIKI KAISHA, Osaka-shi, Osaka (JP)

(72) Inventors: Satoshi MORISHITA, Osaka-shi, Osaka (JP); Tetsuya TAMIYA, Osaka-shi, Osaka (JP); Yutaka NAKAYAMA, Osaka-shi, Osaka (JP)

(73) Assignee: SHARP KABUSHIKI KAISHA, Osaka-shi, Osaka (JP)

(21) Appl. No.: 14/772,283

(22) PCT Filed: Jan. 27, 2014
(86) PCT No.: PCT/JP2014/051694

§ 371 Date: Sep. 2, 2015

(30) Foreign Application Priority Data
Apr. 12, 2013 (JP) 2013-083892

(51) Int. Cl. H01L 29/20; H01L 29/778

(52) U.S. Cl. CPC H01L 29/2003; H01L 29/778

(57) ABSTRACT

A nitride semiconductor device includes a substrate, a nitride semiconductor laminate, and an electrode metal layer. The electrode metal layer includes a first metal layer joined to the nitride semiconductor laminate and having a fine columnar structure including a plurality of columns, and a second metal layer disposed on the first metal layer and having a fine columnar structure including a plurality of columns. An average size of the columns of the fine columnar structure of the second metal layer in a column width direction is larger than an average size of the columns of the fine columnar structure of the first metal layer in a column width direction.

### TECHNICAL FIELD

The present invention relates to a nitride semiconductor device.

### BACKGROUND ART

As disclosed in Japanese Unexamined Patent Application Publication No. 2006-196764 (PTL 1), nitride semiconductor devices that have GaN/AlGaN heterojunctions have been conventionally known. According to this conventional nitride semiconductor device, a Ni layer or a TiₓW₁₋ₓN layer that forms a sufficiently high Schottky barrier is formed on a GaN-based compound semiconductor layer, and a low-resistance metal layer is formed on the Ni layer or the TiₓW₁₋ₓN layer so as to form a gate electrode.

PTL 1 describes that, in the gate electrode, the TiₓW₁₋ₓN layer is useful as a material that forms a Schottky barrier and also serves as a diffusion barrier that suppresses diffusion of the metal in the low-resistance metal layer formed on the TiₓW₁₋ₓN layer into the GaN-based compound semiconductor layer, and that the leak current to the gate electrode is suppressed as a result.

### CITATION LIST

### Patent Literature

PTL 1: Japanese Unexamined Patent Application Publication No. 2006-196764

### SUMMARY OF INVENTION

### Technical Problem

However, according to the conventional nitride semiconductor device, the leak current to the gate electrode is suppressed to some degree but insufficiently, and there has been a problem that the leak current to the gate electrode cannot be sufficiently decreased despite adjustment of the annealing conditions and film thickness.

An object of the present invention is to provide a nitride semiconductor device that can sufficiently decrease the leak current to the gate electrode.

### Solution to Problem

The present inventors have conducted extensive studies on the leak current to the gate electrode (hereinafter referred to as gate leak current) and found that when a metal material having a fine columnar structure is used as a metal material for forming a gate electrode by lamination, the gate leak current can be significantly decreased and the gate leak current failure rate can be significantly improved.

The physical reason why a fine columnar structure of a metal material for a gate electrode affects gate leak current has not been clear. The present inventors have conducted experiments and found that the gate leak current can be significantly reduced when a gate electrode includes a first metal layer joined to a nitride semiconductor laminate and having a fine columnar structure including a plurality of columns and a second metal layer disposed on the first metal layer and having a fine columnar structure including a plurality of columns, in which the average size of the columns of the second metal layer in a column width direction is larger than the average size of the columns of the first metal layer in a column width direction.

The present inventors have discovered for the first time through experiments that the gate leak current is further improved when the first metal layer and the second metal layer are formed by using particular materials and the average size of the columns of the fine columnar structure of each of the metal layers in the column width direction is within a particular range.

The present invention has been made based on the finding that the fine columnar structure of the gate electrode significantly affects the gate leak current, the finding being made by the present inventors based on experiments.

In other words, a nitride semiconductor device according to the present invention includes:

a substrate;

a nitride semiconductor laminate formed on the substrate and having a heterointerface; and

an electrode metal layer formed on the nitride semiconductor laminate.

The electrode metal layer includes

a first metal layer joined to the nitride semiconductor laminate and having a fine columnar structure including a plurality of columns, and

a second metal layer disposed on the first metal layer and having a fine columnar structure including a plurality of columns.

An average size of the columns of the second metal layer in a column width direction is larger than an average size of the columns of the first metal layer in a column width direction.

According to an embodiment of the nitride semiconductor device,

the fine columnar structure of the first metal layer contains tungsten nitride, and

the average size of the columns of the first metal layer in the column width direction is 5 nm or more and 25 nm or less.

According to an embodiment of the nitride semiconductor device,

the average size of the columns of the second metal layer in the column width direction is 30 nm or more and 150 nm or less.

According to an embodiment of the nitride semiconductor device,

the second metal layer contains tungsten.

According to an embodiment of the nitride semiconductor device,

the second metal layer includes a tungsten layer and a titanium nitride layer.

### Advantageous Effects of Invention

As apparent from the description above, because the nitride semiconductor device of the present invention includes an electrode metal that includes a first metal layer joined to a nitride semiconductor laminate and having a fine columnar structure including plural columns and a second metal layer disposed on the first metal layer and having a fine columnar structure including plural columns in which the average size of the columns of the second metal layer in the column width direction is larger than the average size of the columns of the first metal layer in the column width direction, the gate leak current can be sufficiently decreased when a gate electrode is formed by using this electrode metal.

### BRIEF DESCRIPTION OF DRAWINGS

FIG. 1 is a cross-sectional view of a nitride semiconductor device according to a first embodiment of the present invention.

FIG. 2 is a cross-sectional view illustrating a step of a method for producing the nitride semiconductor device.

FIG. 3 is a cross-sectional view illustrating a step following FIG. 2.

FIG. 4 is a cross-sectional view illustrating a step following FIG. 3.

FIG. 5 is a cross-sectional view illustrating a step following FIG. 4.

FIG. 6 is a cross-sectional view illustrating a step following FIG. 5.

FIG. 7 is a cross-sectional view illustrating a step following FIG. 6.

FIG. 8 is a scanning electron microscope image showing a cross-sectional structure of a gate electrode of the nitride semiconductor device.

FIG. 9 is a graph showing results of line analysis of the scanning electron microscope image shown in FIG. 8.

FIG. 10 is a scanning electron microscope image showing a cross-sectional structure of a gate electrode of a nitride semiconductor device of a comparative example.

FIG. 11 is a graph showing results of line analysis of the scanning electron microscope image shown in FIG. 10.

FIG. 12 is a graph showing the relationship between the average size of the columns of a fine columnar structure of a first metal layer of the nitride semiconductor device in column width direction and the gate leak current failure rate.

FIG. 13 is a graph showing the relationship between the average size of columns of a fine columnar structure of a second metal layer of the nitride semiconductor device in the column width direction and the gate leak current failure rate.

FIG. 14 is a scanning electron microscope image showing a cross-sectional structure of a gate electrode of a nitride semiconductor device according to a second embodiment of the present invention.

FIG. 15 is a graph showing the relationship between the average size of the columns of a fine columnar structure of a second metal layer of the nitride semiconductor device in column width direction and the gate leak current failure rate.

### DESCRIPTION OF EMBODIMENTS

The present invention will now be described in further detail through embodiments illustrated in the drawings.

### First Embodiment

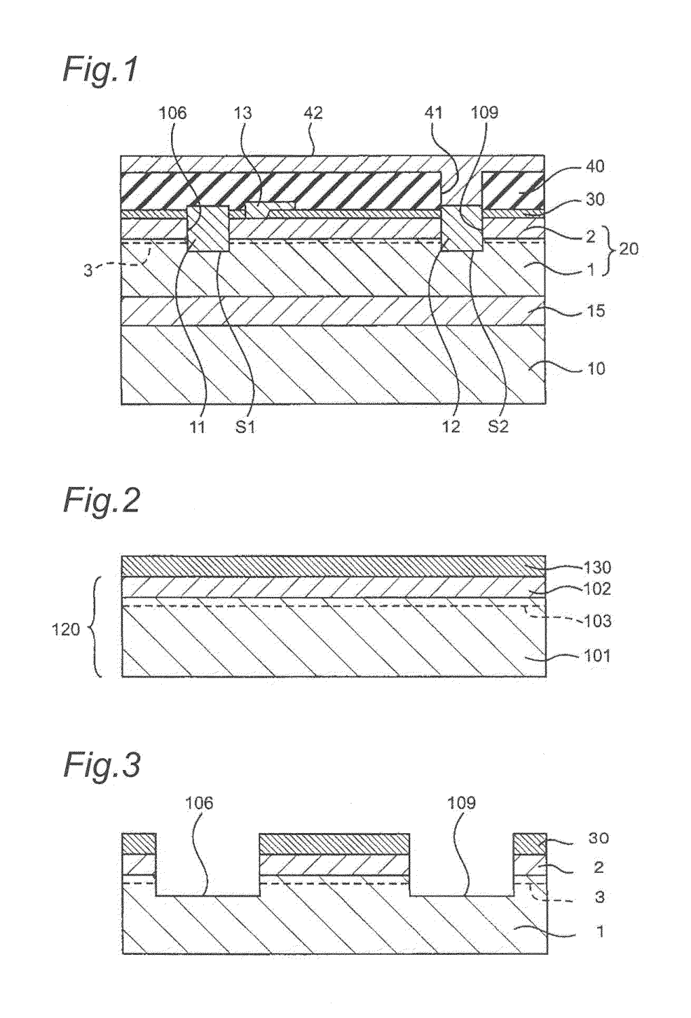

FIG. 1 is a cross-sectional view of a GaN-based hetero-junction field effect transistor (HFET) according to a first embodiment of the present invention.

The nitride semiconductor device includes, as illustrated in FIG. 1, a Si substrate 10, an undoped AlGaN buffer layer 15 formed on the Si substrate 10, and a nitride semiconductor laminate 20 formed on the undoped AlGaN buffer layer 15. The nitride semiconductor laminate 20 is constituted by an undoped GaN layer 1 and an undoped AlGaN layer 2. A 2DEG layer (two-dimensional electron gas layer) 3 occurs near the interface between the undoped GaN layer 1 and the undoped AlGaN layer 2.

An AlGaN layer having a composition with a smaller band gap than the AlGaN layer 2 may be used instead of the GaN layer 1. A layer composed of GaN and having a thickness of about 1 nm may be provided as a cap layer on the AlGaN layer 2, for example. Although the nitride semiconductor laminate 20 is constituted by two semiconductor layers, the number of layers is not limited to this and the nitride semiconductor laminate may be constituted by three nitride semiconductor layers.

The nitride semiconductor device further includes a source electrode 11 and a drain electrode 12. The source electrode 11 and the drain electrode 12 are formed on the AlGaN layer 2 and are separated from each other by a gap. The source electrode 11 and the drain electrode 12 are formed in recesses 106 and 109 that penetrate through the AlGaN layer 2 and the 2DEG layer 3 and reach the GaN layer 1. A gate electrode 13 is formed on the AlGaN layer 2, between the source electrode 11 and the drain electrode 12, and at a position closer to the source electrode. The source electrode 11 and the drain electrode 12 are ohmic electrodes and the gate electrode 13 is a Schottky electrode. The source electrode 11, the drain electrode 12, the gate electrode 13, and an active region constitute the HFET. The gate electrode 13 is one example of a metal electrode layer.

The active region is a region in the nitride semiconductor laminate 20 (GaN layer 1 and AlGaN layer 2) where carriers flow between the source electrode 11 and the drain electrode 12 in response to voltage applied to the gate electrode 13.

In order to protect the AlGaN layer 2, an insulating film 30 composed of SiO₂ is formed on the AlGaN layer 2. An interlayer insulating film 40 composed of polyimide is formed on the insulating film 30 so as to cover the source electrode 11, the drain electrode 12, and the gate electrode 13. Vias 41 that function as contacts are formed in the interlayer insulating film 40 so as to be respectively located on the source electrode 11, the drain electrode 12, and the gate electrode 13 (the vias on the source electrode 11 and the gate electrode 13 are not illustrated in FIG. 1). Part of a drain electrode pad 42 fills the via 41 and a connection to the drain electrode pad 42 is established.

The material of the insulating film 30 is not limited to SiO₂ and may be SiN, Al₂O₃, or the like. In particular, the insulating film 30 may have a multilayer structure constituted by a non-stoichiometric SiN film formed on the semiconductor layer to suppress current collapse and an SiO₂ film or a SiN film for surface protection. The material of the interlayer insulating film 40 is not limited to polyimide and may be an insulating material such as a SiO₂ film produced by p-CVD (plasma chemical vapor deposition), a SOG (spin-on-glass), or BPSG (borophosphosilicate glass).

The term “current collapse” here refers to a phenomenon in which the ON-resistance of a transistor during high-voltage operation becomes higher than the ON-resistance of the transistor during low-voltage operation.

In the nitride semiconductor device having the above-described structure, the channel layer is controlled by applying voltage to the gate electrode 13 so as to turn ON and OFF the HFET having the source electrode 11, the drain electrode 12, and the gate electrode 13. This HFET is a normally ON transistor that enters an OFF state by occurrence of a depleted layer in the GaN layer 1 under the gate electrode 13 when negative voltage is being applied to the gate electrode 13 and enters an ON state as the depleted layer in the GaN layer 1 under the gate electrode 13 disappears in the absence of voltage applied to the gate electrode 13.

Next, a method for producing the GaN-based HFET is described with reference to FIGS. 2 to 7. In FIGS. 2 to 7, the Si substrate 10 and the AlGaN buffer layer 15 are omitted from the drawings and the size and spacing of the gate electrode 13, the source electrode 11, and the drain electrode 12 are changed to promote understanding.

First, as illustrated in FIG. 2, an AlGaN buffer layer 15, a GaN layer 101, and an AlGaN layer 102 are formed one after another on the Si substrate 10 by an MOCVD (metal organic chemical vapor deposition) method. The thickness of the GaN layer 101 is, for example, 1 μm and the thickness of the AlGaN layer 102 is, for example, 30 nm. The GaN layer 101 and the AlGaN layer 102 constitute a nitride semiconductor laminate 120.

An insulating film 130 (for example, SiO₂) is formed on the AlGaN layer 102 by, for example, a plasma CVD (chemical vapor deposition) method so as to have a thickness of 200 nm. At this stage, a 2DEG layer 103 forms near the heterointerface between the GaN layer 101 and the AlGaN layer 102.

A photoresist (not shown) is applied to the insulating film 130 and patterned, and portions where the ohmic electrodes are to be formed are removed by dry etching. As a result, as illustrated in FIG. 3, recesses 106 and 109 that extend from the upper surface of the insulating film 130 to an upper portion of the GaN layer 101 so as to be deeper than the 2DEG layer 103 are formed. The depth of the recesses 106 and 109 from the surface of the AlGaN layer 102 may be any as long as the recesses are deeper than the 2DEG layer 103, and is, for example, 50 nm.

The dry etching is performed by using a chlorine-based gas while the self-bias potential Vdc of a RIE (reactive ion etching) device is set to 180 V or more and 240 V or less.

After formation of the recesses 106 and 109, the surfaces of the recesses 106 and 109 are subjected to an O₂ plasma treatment, and washed with HCl/H₂O₂ and then with BHF (buffered hydrofluoric acid) or 1% HF (hydrofluoric acid). Annealing is performed (for example, at 500° C. to 850° C.) to reduce the etching damage caused by dry etching.

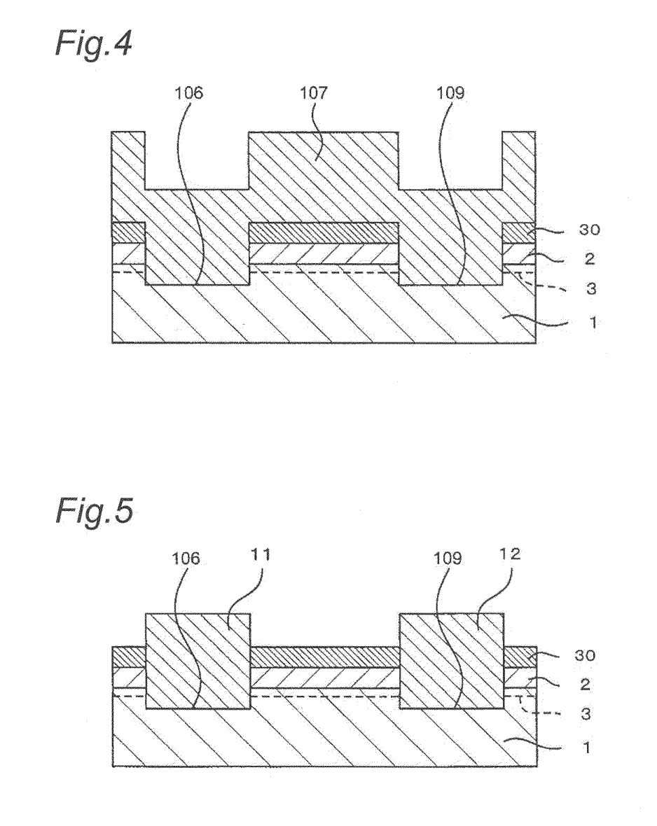

Next, as illustrated in FIG. 4, Ti/Al/TiN are stacked by sputtering on the insulating film 30 and in the recesses 106 and 109 so as to form a multilayer metal film 107 that will be formed into ohmic electrodes. The TiN layer is a cap layer for protecting the Ti/Al layers from the subsequent steps.

In forming the multilayer metal film 107 by sputtering, a small amount of oxygen (for example, 5 sccm) is supplied into a chamber during formation of the Ti film. The flow rate of the oxygen into the chamber is at the level that does not generate Ti oxides.

During sputtering, for example, 50 sccm of oxygen may be supplied to the inside of the chamber for 5 minutes prior to forming the Ti film instead of supplying a small amount of oxygen into the chamber during formation of the Ti film. Alternatively, Ti and Al may be sputtered simultaneously or Ti and Al may be vapor-deposited instead of sputtering.

Next, as illustrated in FIG. 5, typical photolithography and dry etching techniques are performed to form a pattern of the source electrode. 11 and the drain electrode 12.

The substrate on which the source electrode 11 and the drain electrode 12 are formed is annealed at 400° C. or higher and 500° C. or lower for 10 minutes or longer so as to obtain ohmic contact between the 2DEG layer 3 and the source electrode 11 and the 2DEG layer 3 and the drain electrode 12.

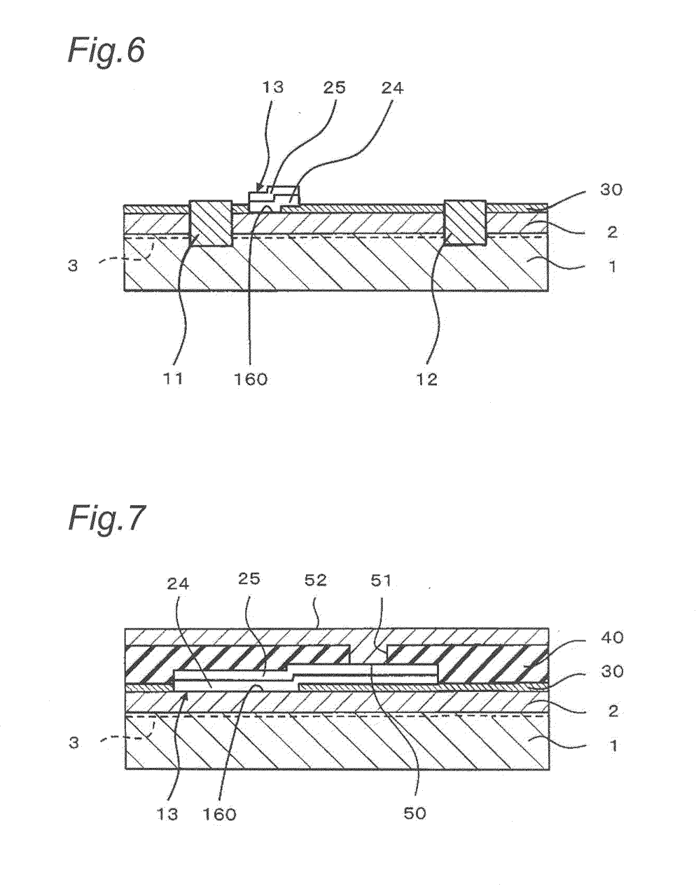

Next, as illustrated in FIG. 6, a mask is formed on a photoresist (not illustrated) by photolithography, and a region in the insulating film 30 where the gate electrode 13 is to be formed between the source electrode 11 and the drain electrode 12 is removed by etching so as to form a recess 160.

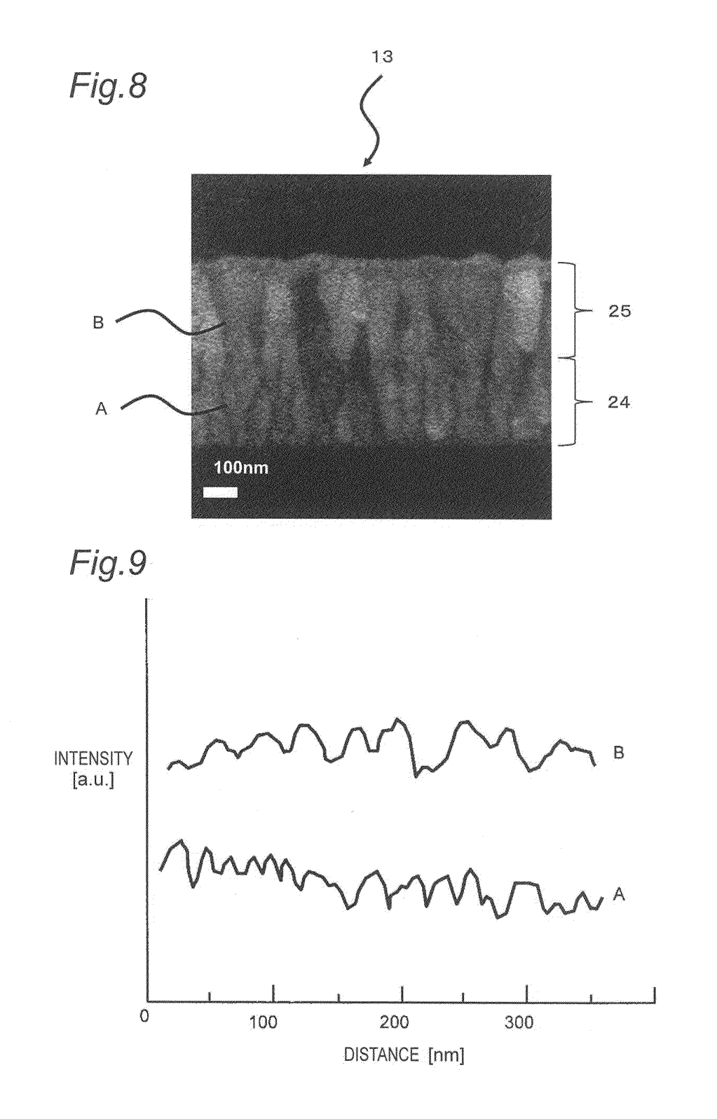

A gate metal film is formed on the photoresist and in the recess 160 by sputtering so as to have a thickness in the range of 150 nm to 250 nm, and then the gate electrode 13 protruding from the insulating film 30 is formed by lift-off. The gate electrode 13 is constituted by a first metal layer 24 that has a fine columnar structure that includes plural columns A (see FIG. 8) and a second metal layer 25 disposed on the first metal layer 24 and having a fine columnar structure that includes plural columns B (see FIG. 8). The junction between the first metal layer 24 and the AlGaN layer 2 is a Schottky junction.

In the gate electrode 13, W (tungsten) nitride is used in the first metal layer 24 and W is used in the second metal layer 25.

The columns A and B of the fine columnar structures of the first metal layer 24 and the second metal layer 25 each extend in a direction substantially parallel to the layer thickness direction. The lower ends of the columns A of the fine columnar structure of the first metal layer 24 are joined to the upper surface of the AlGaN layer 2 and the upper ends are joined to the lower surface of the second metal layer 25. The lower ends of the columns B of the fine columnar structure of the second metal layer 25 are joined to the upper surface of the first metal layer 24.

The gate electrode 13 may be any as long as a Schottky junction is formed between the first metal layer 24 and the AlGaN layer 2. For example, Ti nitride may be used in the first metal layer 24, or a non-stoichiometric thin film, such as a SiN film may be formed between the first metal layer 24 and the AlGaN layer 2 so as to join the first metal layer 24 to the AlGaN layer 2 via the thin film.

Next, an interlayer insulating film 40 is formed on the insulating film 30. A region of the interlayer insulating film 40 that lies on the gate electrode 13 is dry-etched with fluorine-based gas. As a result, as shown in FIG. 7, an interlayer insulating film 40 with a via 51 formed therein is obtained. A part of a gate electrode pad 52 in the via 51 is connected to the gate electrode 13. Vias 41 are formed in the interlayer insulating film 40 so as to be located on the source electrode 11 (see FIG. 1) and the drain electrode 12 (see FIG. 1) by dry etching in the same manner (Although the via on the source electrode 11 is not illustrated, the via 41 on the drain electrode 12 is illustrated in FIG. 1). The vias 41 are filled with an electrode pad material so as to form a nitride semiconductor device illustrated in FIG. 1.

Regarding the embodiment described above, a gate electrode 13 was prepared by setting the conditions for forming a W nitride film used as the first metal layer 24 and a W film used as the second metal layer 25 of the gate electrode 13 as described below. FIG. 8 illustrates an example of a cross-sectional structure of the gate electrode 13 prepared by the production method.

### (W Nitride Film)

Ar flow rate: 45 to 110 sccm

N₂ flow rate: 135 to 180 sccm

Chamber inner pressure: 35 to 83 mTorr

DC output: 1000 to 1600 W

Film forming temperature: 300° C.

### (W Film)

Ar flow rate: 45 to 80 sccm

Chamber inner pressure: 4 to 10 mTorr

DC output: 1000 to 1600 W

Film forming temperature: 300° C.

The average size of the columns A of the fine columnar structure of the W nitride film prepared under the above-described conditions was 23.2 nm in the column width direction. The average size of the columns B of the fine columnar structure of the W film was 34.4 nm in the column width direction. In the GaN-based HFET of this embodiment that used the gate electrode 13, the gate leak current in the OFF state in which 0 V was applied to the drain electrode 12, 0 V was applied to the source electrode 111, and −20 V was applied to the gate electrode 13 was 0.7 nA. When a gate leak current of 2.0 nA or higher was assumed to be fail, the failure rate was 0.6%.

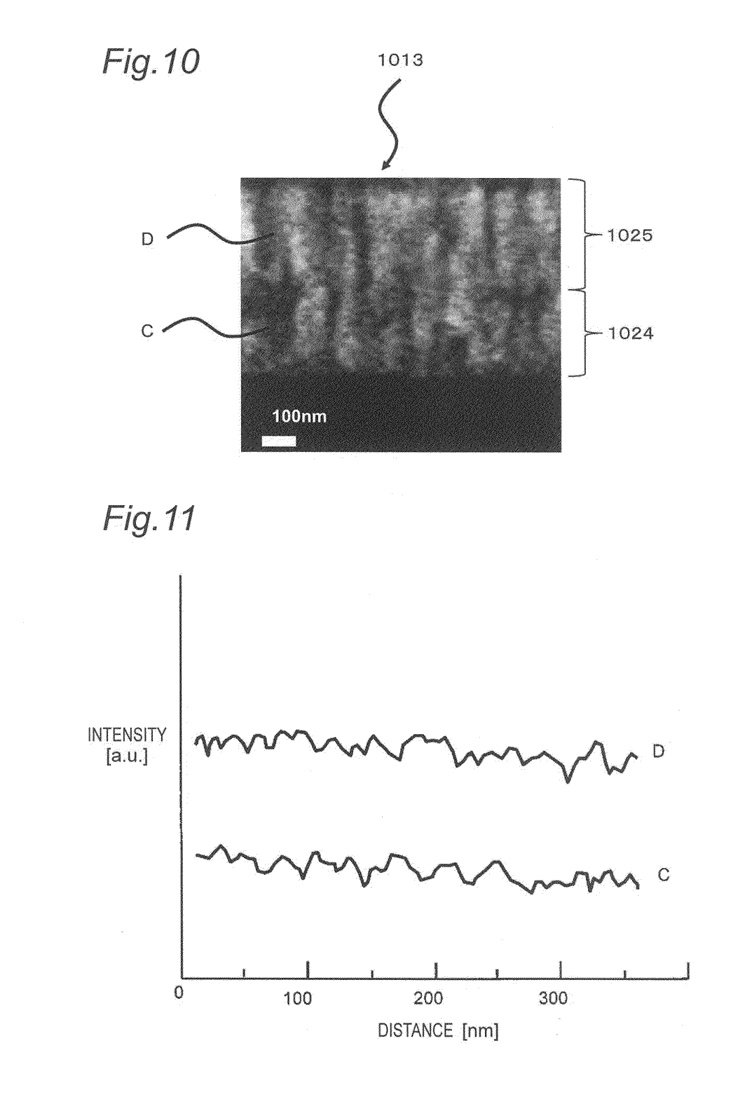

As a comparative example, a GaN-based HFET equipped with a gate electrode 1013 illustrated in FIG. 10 was prepared. In the gate electrode 1013, a W nitride film in which the average size of columns C in a fine columnar structure was 24.0 nm in the column width direction was used as a first metal layer 1024 and a W film in which the average size of columns D in a fine columnar structure was 22.5 nm in the column width direction was used as a second metal layer 1025. The gate leak current of this comparative example GaN-based HFET was 1.5 nA and the gate leak current failure rate was 93%.

The method for calculating the average size of the columns of the fine columnar structure in the column width direction used in the present invention will now be described. A substrate of a target nitride semiconductor device is cleaved to expose a cross section of a gate electrode and the cleaved portion is observed with a scanning electron microscope as illustrated in FIGS. 8 and 10. When an electron beam of the scanning electron microscope is scanned in a direction (the direction perpendicular to the layer thickness direction) perpendicular to the length direction of the columns of the fine columnar structures of the first metal layer and the second metal layer, line analysis images of secondary electrons illustrated in FIGS. 9 and 11 are obtained. The intensity of the line analysis images corresponds to the profile of the irregularities on the surfaces of the fine columnar structures scanned by the electron beam. Thus, the average of half widths of the protruding portions of the line analysis image within the scanned range was assumed to be the average size of the columns of the fine columnar structure of the target nitride semiconductor device in the column width direction.

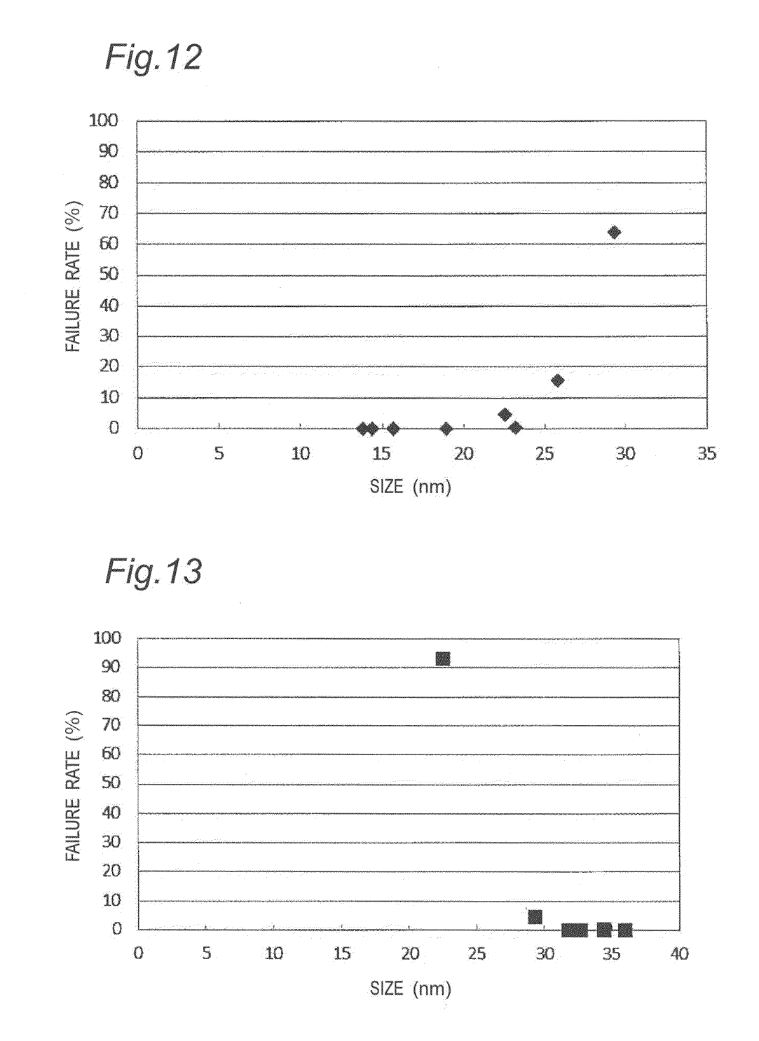

FIG. 12 shows the relationship between the average size of the columns A of the fine columnar structure of the first metal layer 24 of the gate electrode 13 of the GaN-based HFET in the column width direction and the gate leak current failure rate. FIG. 13 shows the relationship between the average size of the columns B of the fine columnar structure of the second metal layer 25 of the gate electrode 13 of the GaN-based HFET in the column width direction and the gate leak current failure rate.

FIG. 12 shows that the gate leak current failure rate falls below 5% when the average size of the columns A of the fine columnar structure of the first metal layer 24 is decreased to 25 nm or less in the column width direction. This is probably because an average size of the columns A exceeding 25 nm in the column width direction increases the inner stress of the first metal layer 24 and the leakage at the interface between the first metal layer 24 and the AlGaN layer 2 is increased. However, when the average size of the columns A of the fine columnar structure of the first metal layer 24 is less than 5 nm in the column width direction, a fine columnar structure is no longer obtained and the inner stress between the first metal layer 24 and the second metal layer 25 is increased. As a result, adhesion between the first metal layer 24 and the second metal layer 25 is decreased and separation of the second metal layer 25 is likely to occur.

The average size of the columns A of the fine columnar structure in the column width direction has shown a decreasing tendency as the DC output is decreased within the range of 1000 to 1600 W or the N₂/Ar flow rate ratio is increased during the formation of the W nitride film used as the first metal layer 24. In particular, decreasing the total flow rate of N₂ and Ar was effective in forming a fine columnar structure in which the average size of the columns A in the column width direction is small. In a pressure range of 35 to 83 mTorr inside the chamber, decreasing the total flow rate of N₂ and Ar and decreasing the chamber inner pressure were effective for decreasing the average size of the fine columnar structure in the column width direction. This is probably because decreasing the chamber inner pressure decreases scattering of the sputtered particles and increases the growth rate of the columnar structure.

FIG. 13 shows that the gate leak current failure rate falls below 1% when the average size of the columns B of the fine columnar structure of the second metal layer 25 is 30 nm or more in the column width direction. This is probably due to the following reason. When the average size of the columns B of the fine columnar structure of the second metal layer 25 is adjusted to less than 30 nm in the column width direction, the average size of the columns B of the fine columnar structure of the second metal layer 25 in the column width direction approaches the average size of the underlying columns A of the fine columnar structure of the first metal layer 24 in the column width direction, thereby enhancing the structural continuity (continuity of grain boundaries). As a result, during dry etching performed to form a via 51, plasma penetrates through the gate electrode 13 from a contact 50 (see FIG. 7) at the bottom of the via 51 and reaches insulating film 30, the insulating film 30 is damaged by active species in the plasma, and thus gate leak current increases and the gate leak current failure rate increases. When the average size of the fine columnar structure of the second metal layer 25 is 30 nm or more in the column width direction, the structural continuity with the fine columnar structure of the first metal layer 24 is decreased, and spreading of damage from the contact 50 to the insulating film 30 during dry etching is suppressed. Thus, the gate leak current can be decreased and the gate leak current failure rate can be decreased.

When the average size of the columns B of the fine columnar structure of the second metal layer 25 exceeds 150 nm in the column width direction, a fine columnar structure is no longer obtained and the structural continuity between the first metal layer 24 and the second metal layer 25 can be further decreased but the inner stress of the second metal layer 25 is increased. As a result, adhesion to the first metal layer 24 is decreased and separation of the second metal layer 25 is likely to occur. Accordingly, the second metal layer 25 must have a fine columnar structure and the average size thereof is preferably less than 150 nm in the column width direction.

The average size of the columns A of the fine columnar structure in the column width direction has shown a decreasing tendency as the DC output is increased within the range of 1000 to 1600 W during the formation of the W film used as the second metal layer 25. However, in the Ar flow rate range of 40 to 80 sccm, decreasing the Ar flow rate and decreasing the chamber inner pressure were effective for forming a fine columnar structure with high adhesion to the first metal layer 24. This is probably because decreasing the Ar flow rate and decreasing the chamber inner pressure decreases scattering of sputtered particles and increases the growth rate of the columnar structures in the length direction.

It has been found that the gate leak current failure rate can be significantly improved since the gate leak current can be significantly reduced by making the average size of the columns B of the fine columnar structure of the second metal layer 25 in the column width direction larger than the average size of the columns A of the fine columnar structure of the first metal layer 24 in the column width direction. In particular, the gate leak current failure rate can be further improved by decreasing the average size of the columns A of the fine columnar structure of the first metal layer 24 to 25 nm or less in the column width direction and increasing the average size of the columns B of the fine columnar structure of the second metal layer 25 to 30 nm or more in the column width direction.

### Second Embodiment

Next, a GaN-based HFET according to a second embodiment of the present invention is described. The GaN-based HFET according to the second embodiment basically has the same structure as the GaN-based HFET of the first embodiment and the production steps are similar to those of the GaN-based HFET of the first embodiment. Accordingly, the descriptions related to FIGS. 1 to 7 are incorporated herein so as to omit the descriptions of the structure and the production method. In the description below, the same structural parts as those of the GaN-based HFET of the first embodiment are referred to by the same reference number used in the first embodiment.

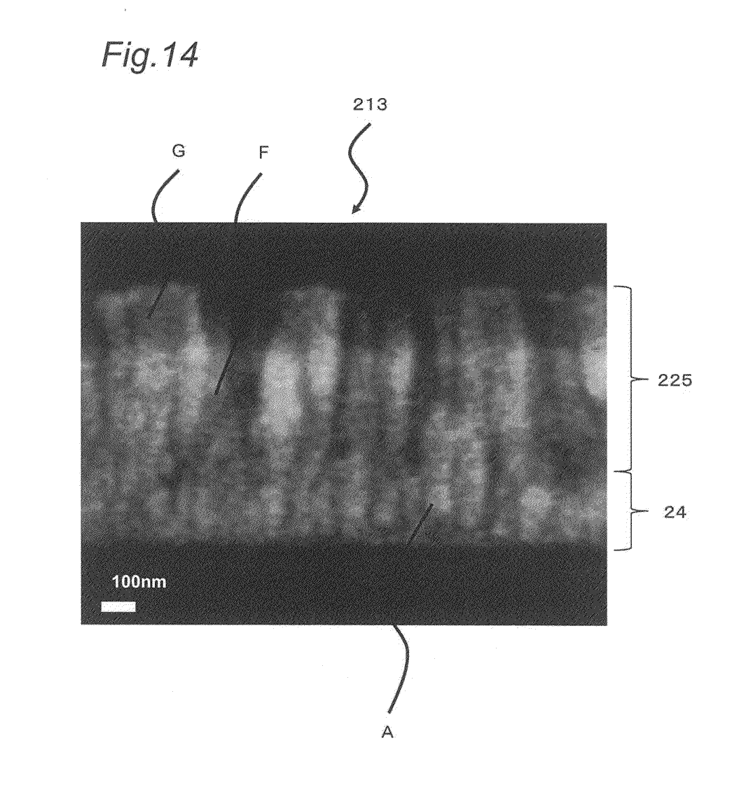

The GaN-based HFET of the second embodiment differs only in that a second metal layer 225 (see FIG. 14) constituted by two layers, a W film and a Ti film, is used instead of the second metal layer 25. In the second embodiment, the conditions for preparing a W nitride film used as the first metal layer 24 and a W film and a Ti film used as the second metal layer 225 were set as follows.

### (W Nitride Film)

Ar flow rate: 45 to 110 sccm

N₂ flow rate: 135 to 180 sccm

Chamber inner pressure: 35 to 83 mTorr

DC output: 1000 to 1600 W

Film forming temperature: 300° C.

### (W Film)

Ar flow rate: 40 to 80 sccm

Chamber inner pressure: 4 to 10 mTorr

DC output: 1000 to 1600 W

Film forming temperature: 300° C.

### (Ti Film)

Ar flow rate: 25 to 30 sccm

N₂ flow rate: 100 to 120 sccm

Chamber inner pressure: 4 to 10 mTorr

DC output: 4000 to 5000 W

Film forming temperature: 50° C.

FIG. 14 illustrates an example of a cross-sectional structure of a gate electrode 213 obtained as above. The average size of columns A of the fine columnar structure of the W nitride film, the average size of columns F of the fine columnar structure of the W film, and the average size of columns G of the fine columnar structure of the Ti nitride were, respectively, 23.2 nm, 36.8 nm, and 33.7 nm in the column width direction.

The method for calculating the average size of the columns of the fine columnar structure of the second metal layer constituted by two layers in the column width direction will now be described. A Si substrate 10 of a target nitride semiconductor device is cleaved so as to expose a cross section of the gate electrode 213 and the cleaved portion is observed with a scanning electron microscope as illustrated in FIG. 14. The electron beam of the scanning electron microscope is scanned in a direction (direction perpendicular to the layer thickness direction) perpendicular to the length direction of the columns A of the fine columnar structure of the first metal layer 24 and the columns F and G of the fine columnar structure of the second metal layer 225. As a result, line analysis images of secondary electrons shown in FIGS. 9 and 11 are obtained from the first metal layer 24 and the two layers constituting the second metal layer 225, respectively. The intensity of the line analysis images corresponds to the profile of the irregularities on the surfaces of the fine columnar structures scanned by the electron beam. Thus, the average of half widths of the protruding portions of the line analysis image within the scanned range was assumed to be the average size of the columns of the fine columnar structure of the target nitride semiconductor device in the column width direction.

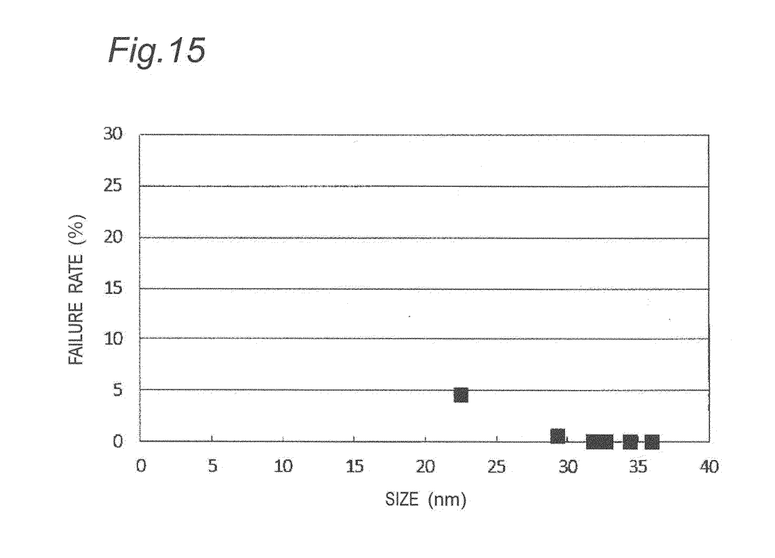

FIG. 15 is a graph illustrating the relationship between the average size of the columns F and G of the fine columnar structure of the second metal layer 125 of the GaN-based HFET in the column width direction and the gate leak current failure rate.

FIG. 15 shows that the gate leak current failure rate is 0% when the average size of the columns F and G of the fine columnar structure of the second metal layer 225 is 30 nm or more in the column width direction. This is probably because the structural continuity with the fine columnar structure of the first metal layer 24 is further decreased when the fine columnar structure of the second metal layer 225 has a two layer structure constituted by a W film and a Ti nitride, and damage on the insulating film 130 inflicted by plasma during dry etching performed to form the via 51 can be suppressed.

It has been found that the gate leak current failure rate can be further improved when the second metal layer 225 is constituted by a W film and a Ti film compared to when the second metal layer 25 constituted by only a W film is used.

For the purposes of this embodiment, “the average size of the columns F and G of the fine columnar structure of the second metal layer 225 in the column width direction is larger than the average size of the columns A of the fine columnar structure of the first metal layer 24 in the column width direction” means that the average size of the columns F and the average size of the columns G of the two-layer fine columnar structure of the second metal layer 225 in the column width direction are each larger than the average size of the columns A of the first metal layer in the column width direction (in other words, A<F and A<G).

In the first and second embodiments described above, the GaN-based HFET includes a Si substrate. However, the substrate is not limited to a Si substrate and may be a sapphire substrate or a SiC substrate. In such a case, nitride semiconductor layers may be grown on a sapphire substrate or a SiC substrate.

According to an embodiment of the present invention, nitride semiconductor layers may be grown on a substrate composed of a nitride semiconductor as in the case of growing an AlGaN layer on a GaN substrate. In such a case, a buffer layer may be formed between the substrate and the nitride semiconductor layer or a hetero improvement layer may be formed between a first nitride semiconductor layer and a second nitride semiconductor layer of a nitride semiconductor laminate.

In the first and second embodiments, the GaN-based HFET has a recess structure but the structure is not limited to this. The GaN-based HFET may be free of a recess structure and a source electrode and a drain electrode may be formed on an AlGaN layer.

In the first and second embodiments, a GaN-based HFET designed to form a 2DEG layer is used as a nitride semiconductor device. However, the nitride semiconductor device is not limited to this and a field effect transistor having another structure may be used as the nitride semiconductor device.

In the first and second embodiments, a normally ON GaN-based HFET is used as the nitride semiconductor device, but the nitride semiconductor device is not limited to this and may be a normally OFF GaN-based HFET.

Although a gate electrode that forms a Schottky junction is used as an electrode metal layer in the first and second embodiments described above, this structure is not limiting and a field effect transistor that includes an electrode metal layer having an electrode insulating gate structure may be used.

The nitride semiconductor of the nitride semiconductor device of the present invention may be any semiconductor represented by AlₓIn_{y}Ga_{1-x-y}N (x≦0, y≦0, 0≧x+y≧1).

While the specific embodiments of the present invention have been described heretofore, the present invention is not limited to the first and second embodiments described above and various modifications are possible without departing from the scope of the present invention. An appropriate combination of the descriptions of the first and second embodiments may be one embodiment of the present invention. The nitride semiconductor device of the present invention is not limited to a HFET that utilizes 2DEG and the same advantageous effects can be obtained from field effect transistors of other types, such as metal MIS (metal insulator semiconductor) FETs, MOS (metal oxide semiconductor) FETs, and MES (metal semiconductor) FETs.

In other words, the present invention and the embodiments can be summarized as follows.

A nitride semiconductor device of the present invention includes

a substrate 10;

a nitride semiconductor laminate 20 formed on the substrate 10 and having a heterointerface; and

an electrode metal layer formed on the nitride semiconductor laminate 20.

The electrode metal layer includes

a first metal layer 24 joined to the nitride semiconductor laminate 20 and having a fine columnar structure including plural columns A, and

a second metal layer 25 disposed on the first metal layer 24 and having a fine columnar structure including plural columns B.

The average size of the columns B of the second metal layer 25 in a column width direction is larger than the average size of the columns A of the first metal layer 24 in a column width direction.

According to the above-described structure, when a gate electrode 13 is formed by using the metal layer, the gate leak current can be decreased because the electrode metal layer includes a first metal layer 24 joined to the nitride semiconductor laminate 20 and having a fine columnar structure including plural columns A, and a second metal layer 25 disposed on the first metal layer 24 and having a fine columnar structure including plural columns B, and because the average size of the columns B of the second metal layer 25 in a column width direction is larger than the average size of the columns A of the first metal layer 24 in a column width direction.

According to an embodiment of the nitride semiconductor device,

the fine columnar structure of the first metal layer 24 contains tungsten nitride and the average size of the columns A of the first metal layer 24 in the column width direction is 5 nm or more and 25 nm or less.

According to this embodiment, when a gate electrode 13 is formed by using the electrode metal layer, the gate leak current can be decreased by adjusting the average size of the columns A of the fine columnar structure of the first metal layer 24 to 25 nm or less in the column width direction.

Film separation between the first metal layer 24 and the second metal layer 25 can be suppressed by adjusting the average size of the columns A of the fine columnar structure of the first metal layer 24 to 5 nm or less in the column width direction.

According to an embodiment of the nitride semiconductor device, the average size of the columns B of the second metal layer 25 in the column width direction is 30 nm or more and 150 nm or less.

According to this embodiment, when a gate electrode 13 is formed by using the electrode metal layer, the gate leak current can be decreased by adjusting the average size of the columns B of the fine columnar structure of the second metal layer to 25 to 30 nm or more in the column width direction

Film separation between the first metal layer 24 and the second metal layer 25 can be suppressed by adjusting the average size of the columns B of the fine columnar structure of the second metal layer 25 to 150 nm or less in the column width direction.

According to an embodiment of the nitride semiconductor device,

the second metal layer 25 contains tungsten.

According to this embodiment, since the second metal layer 25 contains tungsten, high adhesion is obtained between the first metal layer 24 and the second metal layer 25 and a decrease in yield due to gate leak failure can be suppressed while preventing film separation even when the first metal layer 24 contains tungsten nitride and the average size of the columns B of the fine columnar structure of the second metal layer 25 in the column width direction is different from the average size of the columns A of the fine columnar structure of the first metal layer 24 in the column width direction.

According to an embodiment of the nitride semiconductor device,

the second metal layer 225 is constituted by a tungsten layer and a titanium nitride layer.

According to this embodiment, when a gate electrode 13 is formed by using the electrode metal layer, the gate leak current can be significantly decreased when the second metal layer 225 includes a tungsten layer and a titanium nitride layer compared to when the second metal layer 225 is constituted by a tungsten layer alone.

### REFERENCE SIGNS LIST

1, 101 GaN layer
2, 102 AlGaN layer
3, 103 2DEG layer
10 Si substrate
11 source electrode
12 drain electrode
13, 213 gate electrode
15 AlGaN buffer layer
20, 120 nitride semiconductor laminate
24 first metal layer
25, 225 second metal layer
30, 130 insulating film
40, 140 interlayer insulating film
41, 51 via
42 drain electrode pad
50 contact
52 gate electrode pad
106, 109, 160 recess
A, B column

1. A nitride semiconductor device comprising:
a substrate;
a nitride semiconductor laminate formed on the substrate and having a heterointerface; and
an electrode metal layer formed on the nitride semiconductor laminate,
wherein the electrode metal layer includes
a first metal layer joined to the nitride semiconductor laminate and having a fine columnar structure including a plurality of columns, and
a second metal layer disposed on the first metal layer and having a fine columnar structure including a plurality of columns, and
an average size of the columns of the second metal layer in a column width direction is larger than an average size of the columns of the first metal layer in a column width direction, and
the fine columnar structure of the first metal layer contains tungsten nitride and the average size of the columns of the first metal layer in the column width direction is 5 nm or more and 25 nm or less.

2. (canceled)

3. The nitride semiconductor device according to claim 1,
wherein the average size of the columns of the second metal layer in the column width direction is 30 nm or more and 150 nm or less.

4. The nitride semiconductor device according to claim 1,
wherein the second metal layer contains tungsten.

5. The nitride semiconductor device according to claim 1,
wherein the second metal layer includes a tungsten layer and a titanium nitride layer.

6. The nitride semiconductor device according to claim 3,
wherein the second metal layer includes a tungsten layer and a titanium nitride layer.

7. A nitride semiconductor device comprising:
a substrate;
a nitride semiconductor laminate formed on the substrate and having a heterointerface; and
an electrode metal layer formed on the nitride semiconductor laminate,
wherein the electrode metal layer includes
a first metal layer joined to the nitride semiconductor laminate and having a fine columnar structure including a plurality of columns, and
a second metal layer disposed on the first metal layer and having a fine columnar structure including a plurality of columns, and
an average size of the columns of the second metal layer in a column width direction is larger than an average size of the columns of the first metal layer in a column width direction, and
the second metal layer contains tungsten.

8. A nitride semiconductor device comprising:
a substrate;
a nitride semiconductor laminate formed on the substrate and having a heterointerface; and
an electrode metal layer formed on the nitride semiconductor laminate,
wherein the electrode metal layer includes
a first metal layer joined to the nitride semiconductor laminate and having a fine columnar structure including a plurality of columns, and
a second metal layer disposed on the first metal layer and having a fine columnar structure including a plurality of columns, and
an average size of the columns of the second metal layer in a column width direction is larger than an average size of the columns of the first metal layer in a column width direction, and
the second metal layer includes a tungsten layer and a titanium nitride layer.
